(19) United States
(12) Patent Application Publication
(10) Pub. No.: US 2002/0045299 A1
(43) Pub. Date: Apr. 18, 2002

(54) Method of forming a bottom-gate thin film transistor

(75) Inventor: Nigel D. Young, Redhill (GB)

Correspondence Address: Corporate Patent Counsel, U.S. Philips Corporation, 580 White Plains Road, Tarrytown, NY, 10591, US

(73) Assignee: KONINKLIJKE PHILIPS ELECTRONICS N.V.

(21) Appl. No.: 09/935,880

(22) Filed: Aug. 23, 2001

(30) Foreign Application Priority Data
Aug. 26, 2000 (GB) 0021030.2

(51) Int. Cl. H01L 21/00; H01L 21/84; H01L 21/20

(52) U.S. Cl. 438/160; 438/151; 438/158

(57) ABSTRACT

A method of forming a thin film transistor structure having a bottom-gate metal region (14) separated by an insulating layer (18) from a semiconductor film (20) having a channel region and source/drain regions (22) is disclosed. The method includes a back exposure step in which the gate metal region (14) acts as a mask and as part of the process of the formation of the source/drain regions (22) in the thin film (20) at location to either side of the gate metal region (14), the self-alignment achieved by the back exposure serving to limit the current path between the source/drain region (14) and the channel region (20).

The present invention relates to a method of forming a thin film transistor structure having a bottom-gate metal region separated by an insulating layer from a semiconductor thin film having a channel region and source/drain regions.

Thin film transistors are particularly suitable for use in electro-optical devices, commonly serving as peripheral driving circuits and switching elements. Semiconductor devices provided with such integrated thin film transistors can be used for driving the substrates of active matrix electro-optical devices wherein the semiconductor devices are provided on relatively large and inexpensive insulating substrates. The semiconducting thin film can be formed from amorphous silicon or poly-silicon and the structure can comprise a bottom gate or top-gate structure.

In common with semiconductor fabrication techniques in general, a feature of such a method that serves to define the cost and complexity of forming the thin film transistor structure is the number of mask counts and thus the number of separate mask alignments, required to form the basic structure of the thin film device.

Any variation of the known methods of thin film transistor formation that can reduce the number of mask counts therefore has the potential to advantageously reduce the complexity and cost of producing thin film structures and can also assist in increasing the yield when manufacturing such devices.

U.S. Pat. No. 5,903,014, discusses the provision of a laterally formed n-region which however has the associated disadvantage of introducing an extra mask and/or extra processing stage into the formation process. Also, such increased mask count as exhibited in the state of the art are all the more apparent when further fabrication steps become necessary for example for the formation of CMOS thin film transistor devices.

The relatively high mask count found in the prior art serves to limit the range of electro-optical devices for which otherwise potentially advantageous structures such as poly-silicon CMOS thin film transistor devices could be used, such as for example standard display screens for monitors and televisions.

The present invention seeks to provide for a method of forming a bottom-gate thin film transistor structure having advantages over known such methods particularly with regard to the mask count employed within the method.

According to the present invention, there is provided a method such as that defined above and characterised by a back exposure step using the gate metal region as a mask and as part of the formation of the source/drain regions in the thin film to either side of the gate metal region, the self-alignment achieved by the back exposure serving to limit the current path between the source/drain region and the channel region.

Employing the gate metal region in this manner during the back-exposure step for the formation of the source/drain regions advantageously avoids the need for a specific mask step otherwise used for the formation of a source/drain regions. Thus, in reducing the mask count, a method embodying the invention can advantageously offer a reduction in cost and complexity of the formation of the thin film transistor device. In particular, for N-channel poly-silicon thin film transistor devices, the self alignment of the bottom-gate metal region can advantageously reduce the current path through the source/drain region into the channel region to a length approximately equivalent to the film thickness.

The measure as defined in claim 2 exhibits advantages relating to the reduction in the electric fields otherwise occurring at n+/channel junctions, and as discussed in U.S. Pat. No. 5,903,014, but which can be provided without incurring the relatively high mask count arising in accordance with the method known from that document.

The measure as defined in claim 3 has the advantage that it allows for a good contact to a subsequent metal contact region formed on the source/drain region.

Advantageously, the thin n+ region can be formed by the provision of an extra shallow n− implant immediately after the main n− implant so as to build up the doping at the top of the thin film. Alternatively, and in place of the n− implant, the method can advantageously employ a shallow n+ implant and then allow for subsequent diffusion to produce a graded dopant profile from n+ to n− through the thin film. The dopant also diffuses laterally into the channel region having an advantageous effect with regard to field control.

As an alternative to the use of n+ and/or n− implantation steps, a dopant gas can be introduced into a laser chamber so as to allow for diffusion of the dopant during a laser annealing stage.

The measure as defined in claim 7 has the advantage that further decreases in the mask count and complexity are exhibited by the method.

Advantageously, the second back exposure step is used for the formation of metal contact regions for the source/drain regions.

The measure as defined in claim 9 has the advantage that, particularly for N-channel devices employing n− source/drain regions, it effectively increases the length of, for example, a lightly doped drain region in the direction of current flow so as to thereby ensure that a thin film of a thickness in a region of 0.05 to 0.1 microns will still providing sufficient field relief due to the increased effective length of the lightly doped region.

According to a particular embodiment, the method according to the present invention in forming a thin film transistor structure employs a combination of four mask steps and two back exposures.

A thin film transistor structure can thereby be formed through one of an advantageously reduced number of mask stages and thereby an advantageous decrease in related cost, and complexity and a potential increase in yield.

The measure as defined in claim 10 has the advantage that in view of the decrease in mask count and complexity exhibited, the invention can, for example, render poly-silicon devices competitive with, for example, amorphous silicon devices when considering the formation of electro-optic displays of standard monitor and television sizes.

Advantageously, a CMOS structure can be formed by including a further mask stage at the time of doping the source/drain regions but even in increasing the number of mask stages to five, the formation of a poly-silicon CMOS thin film transistor in accordance with the method of the present invention exhibits an advantageously reduced number of mask steps.

In particular, the method also employs only one ion implant for the formation of the source/drain regions, a single laser anneal subsequent to the said implant and only a single dielectric deposition stage and these features further enhance the relative simplicity and cost-effectiveness of a method embodying the present invention. Of course, if a CMOS structure is required, the number of doping steps required increases to two.

In particular, the present invention can be advantageous employed in the formation of thin film transistor structures for use in active matrix liquid crystal display devices and flat screen display devices in general.

These and other aspects of the invention will be apparent from and elucidated with reference to the embodiments described hereinafter.

The invention is described further hereinafter, by way of example only, with reference to the accompanying drawings in which:

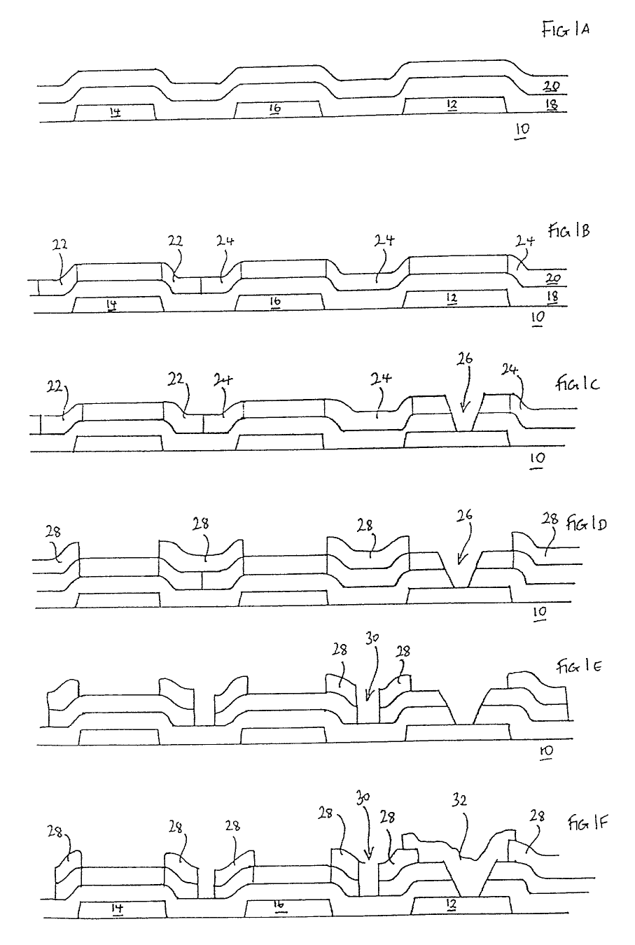

FIGS. 1A-1F illustrate stages in the formation of a polysilicon CMOS thin film transistor structure;

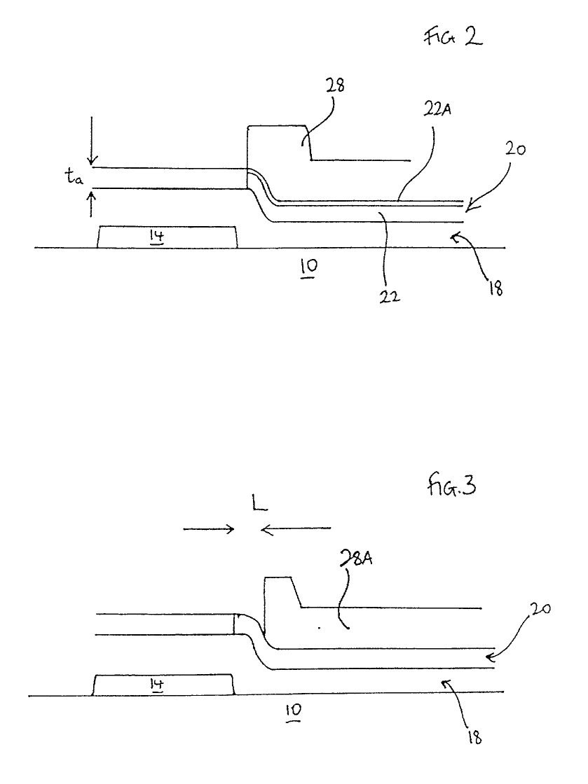

FIG. 2 illustrates a variation on the method of FIGS. 1A-1F;

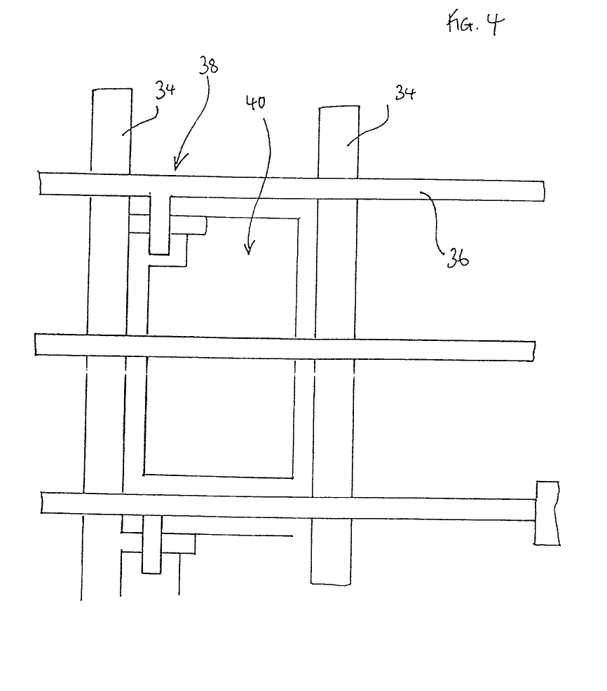

FIG. 3 illustrates a further very specific variation of the step illustrated in FIG. 1E; and

FIG. 4 is a schematic plan view of a display screen comprising thin film transistor structures formed according to the present invention.

Turning first to FIGS. 1A-1F, there are illustrated five stages in the formation of a thin film transistor structure in accordance with the present invention.

In FIG. 1A, a substrate 10 is first provided with a metal layer which is subsequently patterned through a first mask step so as to form bottom-gate metal regions 12, 14 and 16. A dielectric layer 18 is then formed over the substrate and bottom-gate metal structures and a thin film silicon layer 20 subsequently formed on the oxide layer 18.

In the stage illustrated by FIG. 1B, the first of two back exposures and related self-alignments is employed in which the bottom-gate metal region 14 serves as a mask during the formation of the n− source/drain regions 22 thereby forming an N-channel thin film transistor having a bottom-gate 14. A second mask stage is then employed so as to provide for the selective implantation of the n+ dopant so as to form the doped source/drain regions 24 which can subsequently define P-channel thin film transistors which, with the n− source/drain regions 22, form a CMOS structure.

Subsequent to the implantation of the n− and n+ dopant, a laser anneal step is employed.

In FIG. 1C, a third mask stage is employed for opening up a contact via 26 through the silicon thin film 20 and underlined dielectric 18 contact with, for example, the bottom-gate metal contact region 12. In FIG. 1D, the second of the two back exposure steps is undertaken and which is employed as part of a process in providing patterned metal contact regions 28 for contact to the doped source/drain regions. Float off is employed in removing the deposited metal so as to achieve the appropriate patterning as illustrated in FIG. 1D. However, if float off reliability is perceived as a problem, the metal regions could advantageously be sintered into silicon layer.

The fourth mask stage is illustrated in FIG. 1E and wherein each of the metal regions 28, and underlying silicon regions, is etched so as to provide the device islands in the form as illustrated.

Finally, in FIG. 1F a final mask stage is employed so as to provide a patterned ITO layer 32 serving to provide contact through the via 26 to the bottom metal region 12.

As will be appreciated, from the first mask stage employed in FIG. 1A through to the final mask stage in FIG. 1F, only five mask steps will have been required through advantageous use of two separate back exposures and so as to form a polysilicon CMOS thin film transistor structure having ITO contact regions such as that illustrated in FIG. 1F.

Turning now to FIG. 2, there is illustrated a portion of, for example, a thin film transistor employing the bottom-gate metal region 14 and in which the n− doped drain region 22 is provided with an upper n+ layer 22a so as to improve contact between the drain region and the overlying metal region 28. As previously mentioned, the n− doping of the drain region 22 serves to reduce the field at the drain 22 channel 20 interface. In accordance with one aspect of the present invention, the drain can be provided solely as an n− region which can be achieved through self-alignment arising from the back exposure of the bottom metal gate 14 which serves to make the current path from the metal 28, through the n− region 22 to the channel 20 relatively small and, in general, approximately equivalent to the thickness ta of the thin film 20. However, in order to enhance such an arrangement, the method of the present invention can include the provision of the thin n+ region at the top of the thin film 20 and which can be easily achieved by the provision of an extra shallow implant immediately after the initial n− implant. Alternatively, since the laser anneal step will serve to diffuse dopant instances of approximately 0.1 microns, the initial n− implant could be omitted and a shallow n+ implant provided with the above mentioned diffusion serving to produce a graded dopant profile from n+ to n− to the thin film at the drain region.

Alternatively, and insofar as the film thickness might not permit the provision of such a graded dopant profile, an alternative is to effectively increase the length of the lightly doped drain region in the direction of current flow so that, even with a thin film having a thickness in the region of 0.05 microns 0.1 microns, sufficient field relief can still be achieved. The increase of the effective length of the lightly doped drain region can be achieved through appropriate control of the photolithography arising during the second back exposure step of FIG. 1D and which, with reference to FIG. 3, can serve to provide a gap L in the direction of the current flow between the drain and channel 20 which then serves to increase the effective length of the lightly doped drain region 22 in that direction. The limitation in the length of the metal region 28A in this manner therefore advantageously provides for an increase in the effective length of the lightly doped drain in the direction of the aforesaid current flow so as to achieve the required field relief while still advantageously employing a thin film having a thickness in the range noted above.

FIG. 4 illustrates a plan view of part of a display screen comprising a matrix of pixels and including a column line 34 and gate line 36 for providing appropriate control of a thin film transistor 38 formed in accordance with the present invention which, in turn, serves to drive the electrodes of a pixel 40.

Whilst, with such an arrangement, it might not be possible to obtain a full filled shielded pixel, it could nevertheless prove possible to self-align the ITO regions to the columns by using a further back exposure step in which the columns serve as the masks and, when employing CMOS structures, such an arrangement still only requires five mask steps.

To summarise the advantages arising from the method according to the present invention and as when used as part of a CMOS process, there is illustrated below in table 1 a comparison between the characteristics stages of the prior art and a five mask method according to the present invention along with an indication in the reduction in the number of such characteristic stages required.

TABLE 1

| | | | | A- | | | LASER |
|---|---|---|---|---|---|---|---|
| | | | RE- | LIGN- | | ION | AN- |
| | PECUD | SPUTT | SIST | ER | ETCH | DOPE | NEAL |
| GOLD | 4 | 3 | 8 | 8 | 6 | 3 | 1 |
| D | | | | | | | |
| 5 | 2 | 3 | 6 | 5 | 6 | 2 | 1 |
| MASK | | | | | | | |
| PRO- | | | | | | | |
| CESS | | | | | | | |
| SAV- | +2 | 0 | +2 | +3 | 0 | +1 | 0 |
| ING | | | | | | | |

It should be appreciated that the invention is not restricted to the details of the foregoing embodiment and, in particular, the method need not be provided as part of a 5 mask step CMOS process but again rather be provided as part of a 4 mask non CMOS process. Indeed, the method can advantageously be employed in any thin film transistor manufacturing process in which at least one back exposure step is employed as part of the structuring of the semiconductor layer regions provided above and to the side of each bottom-gate metal region and so as to advantageously reduce the number of mask steps by at least one. As of course will be appreciated, even the reduction of in the number of mask steps by one can have a significant advantageous benefit on the decreased complexity and improved cost effectiveness of the method of thin film transistor production concerned.

1. A method of forming a thin film transistor structure having a bottom-gate metal region separated by an insulating layer from a semiconductor film having a channel region and source/drain regions, characterised by a back exposure step using the gate metal region as a mask and as part of the formation of the source/drain regions in the thin film to either side of the gate metal region, the self-alignment achieved by the back exposure serving to limit the current path between the source/drain region and the channel region.

2. A method as claimed in claim 1, and wherein the source/drain region is formed as an n− region.

3. A method as claimed in claim 2, wherein the source/drain region is provided with a thin n+ region at the top thereof.

4. A method as claimed in claim 3, wherein the thin n+ region is formed by the provision of an additional and shallow n− implant subsequent to the initial n− implant so as to build up the doping at the top of the thin film.

5. A method as claimed in claim 3, and including a shallow n+ implant and subsequent diffusion to produce a graded dopant profile from n+ to n− through the thin film.

6. A method as claimed in claim 2, and including a laser annealing stage and wherein a dopant gas is added to the laser chamber and allowing for defusing of the dopant during the laser annealing stage.

7. A method as claimed in any one of the claims 1 to 6, wherein the said back exposure step comprises the first of two back exposure steps, the second also being employed for structuring the device at the source/drain regions of the thin film transistor.

8. A method as claimed in claim 7, wherein the second back exposure step is used for the formation of metal contact regions for the source/drain regions.

9. A method as claimed in claim 8, wherein a photo-lithographic step subsequent to the said second back exposure step is controlled so as to limit the lateral dimension of the metal contact relative to the source/drain region and thereby increase the current path from the channel region through the source/drain region to the metal contact.

10. A method as claimed in claim 6 or 7, and comprising the formation of a substrate:
the deposition and patterning by means of a first mask step of gate metal regions and then the subsequent provision of overlying dielectric layer and subsequent silicon thin film layer;
a first back exposure and bottom-gate alignment step for introducing appropriate dopant into the source/drain regions of the thin film and a second mask step for forming contact vias through the thin film and dielectric layer for the selective opening of a contact region to a bottom gate metal region;
a second back exposure and alignment step for the patterning of metal contact regions for a source/drain regions;
a third mask step for patterning the metal regions and underlying thin film; and
a fourth mask stage for the deposition and patterning of an ITO contact for the said vias.

11. A method as claimed in claim 10, and including an ion implant for the formation of the source/drain regions, a laser anneal subsequent to the said implant and a dielectric deposition stage.
